(19) United States
(12) Patent Application Publication
(10) Pub. No.: US 2026/0058619 A1
(43) Pub. Date: Feb. 26, 2026

(54) RADIO FREQUENCY (RF) POWER AMPLIFIER AND RELATED SIGNAL PROCESSING CIRCUITRY AND METHODS

(71) Applicant: Analogic Corporation, Peaboby, MA (US)

(72) Inventors: Robert G. Haefner, JR., Haverhill, MA (US); Jose Juste-Vinuales, Newburyport, MA (US); Ravindran Sundar, Wilmington, MA (US)

(73) Assignee: Analogic Corporation, Peaboby, MA (US)

(21) Appl. No.: 18/812,906

(22) Filed: Aug. 22, 2024

(51) Int. Cl. H03F 3/24; H03G 3/30; H03H 9/64

(52) U.S. Cl. CPC H03F 3/245; H03G 3/3042; H03H 9/64; H03F 2200/102; H03F 2200/451

(57) ABSTRACT

A power amplifier for producing an amplified radio frequency (RF) signal from an input RF signal includes, inter alia, an RF splitter configured to receive the input RF signal and split the input RF signal into a first split signal and a second split signal; digital processing circuitry configured to receive a digital representation of the first split signal and to produce a gain control signal and a phase control signal; an RF delay stage configured to receive the second split signal and to produce a delayed representation of the second split signal; a gain adjustment stage configured to receive the gain control signal and to adjust a gain based on the gain control signal; a phase adjustment stage configured to receive the phase control signal gain-adjusted signal and to adjust a phase based on the phase control signal, wherein the gain adjustment stage and the phase adjustment stage collectively produce a phase-adjusted and gain-adjusted signal; and an RF power amplifier stage, configured to receive the phase-adjusted and gain-adjusted signal and to produce the amplified RF signal.

### BACKGROUND

### Field

The present disclosure relates to a Radio Frequency (RF) power amplifier and related signal processing circuitry and methods.

### RELATED ART

A design of an RF power amplifier is illustrated in FIG. 1. As shown in FIG. 1, the RF power amplifier 100 includes a RF splitter 104 receiving an input RF signal 102. The RF power amplifier 100 also includes a peak or radio frequency envelope detector 106 electrically connected to the RF splitter 104. A peak or radio frequency envelope detector receives as input a relatively high-frequency amplitude modulated signal and outputs a demodulated envelope of the original signal. A peak or radio frequency envelope detector may use either half-wave or full-wave rectification of the input alternative current (AC) signal to convert the input AC input into a pulsed direct current (DC) signal.

The RF power amplifier 100 also includes an analog to digital converter (ADC) 108, electrically connected to the peak or radio frequency envelope detector 106. The RF power amplifier 100 also includes digital processing circuitry 110 electrically connected to the ADC 108. The digital processing circuitry 110 may include a lookup table for determining gain and phase adjustments. The digital processing circuitry 110 outputs a gain control signal 112 and a phase control signal 114. The RF power amplifier 100 includes a first digital to analog converter (DAC) 116 which is electrically connected to the digital processing circuitry 110 to receive as input the gain control signal 112 and to produce an analog representation of the gain control signal 112. The RF power amplifier 100 includes a second DAC 118 which is electrically connected to the digital processing circuitry 110 to receive as input the phase control signal 114 and to produce an analog representation of the phase control signal 114.

The RF power amplifier 100 includes a gain adjustment stage 120 electrically connected to the RF splitter 104 and the first DAC 116. The gain adjustment stage 120 is configured to receive the analog representation of the gain control signal 112 and the analog signal from the RF splitter 104.

The RF power amplifier 100 includes a phase adjustment stage 122 electrically connected to the gain adjustment stage 120 and the second DAC 118. The phase adjustment stage 122 is configured to receive the analog representation of the phase control signal 114 and the output of the gain adjustment stage 120.

The RF power amplifier 100 also includes a RF power amplifier stage 124 electrically connected to an output of the phase adjustment stage 122 and to the digital processing circuitry 110. The digital processing circuity 110 is further configured to receive an output of the RF power amplifier stage 124 and to use it as feedback to adjust the gain control signal 112 and the phase control signal 114. The output of the RF power amplifier stage 124 may also be electrically connected to an electrical device or system to be powered by the power amplifier. The RF power amplifier 100 is sometimes connected to a Magnetic Resonance Imaging (MRI) system to power a coil of the MRI system.

### BRIEF SUMMARY

In one embodiment, a power amplifier for producing an amplified radio frequency (RF) signal from an input RF signal comprises: an RF splitter configured to receive the input RF signal and split the input RF signal into a first split signal and a second split signal; a digital control portion comprising: digital processing circuitry coupled to the RF splitter, configured to receive a digital representation of the first split signal and to produce a gain control signal and a phase control signal; an analog processing portion comprising: an RF delay stage coupled to the RF splitter, configured to receive the second split signal and to produce a delayed representation of the second split signal; a gain adjustment stage coupled directly or indirectly to the radio frequency delay stage, configured to receive the gain control signal and to adjust a gain based on the gain control signal; a phase adjustment stage coupled directly or indirectly to the radio frequency delay stage gain adjustment stage, configured to receive the phase control signal and to adjust a phase based on the phase control signal, wherein the gain adjustment stage and the phase adjustment stage collectively produce a phase-adjusted and gain-adjusted signal; and an RF power amplifier stage, configured to receive the phase-adjusted and gain-adjusted signal and to produce the amplified RF signal.

Optionally, the RF delay stage of the power amplifier for producing an amplified RF signal from an input RF signal may comprise a surface acoustic wave (SAW) filter. Optionally, the RF delay stage of the power amplifier for producing an amplified RF signal from an input RF signal may be configured to produce the delayed representation of the second split signal having a delay ranging from about 500 nanoseconds to about 2 microseconds. Optionally, the delayed representation of the second split signal of the power amplifier for producing an amplified RF signal from an input RF signal may have a frequency in the range of about 8.5 MHz-500 MHz.

Optionally, the digital processing circuity of the digital control portion of the power amplifier for producing an amplified RF signal from an input RF signal may further comprise a field programmable gate array calibrated to produce a delay that is compatible with a delay of the delayed representation of the second split signal produced by the RF delay stage. Optionally, the digital control portion of the digital processing circuitry of the power amplifier for producing an amplified RF signal from an input RF signal may further comprise: a radio frequency envelope detector coupled to the RF splitter, configured to receive the first split signal, and configured to output a demodulated signal. Optionally, the digital control portion of the digital processing circuitry of the power amplifier for producing an amplified RF signal from an input RF signal may further comprise: an analog to digital converter having at least one input coupled to the radio frequency envelope detector and at least one output coupled to the digital signal processing circuitry.

Optionally, the power amplifier for producing an amplified RF signal from an input RF may further comprise: a gain digital to analog converter having at least one input coupled to the digital signal processing circuitry and having at least one output coupled to the gain adjustment stage. Optionally, the power amplifier for producing an amplified RF signal from an input RF signal, may further comprise: a phase digital to analog converter having at least one input coupled to the digital signal processor and having at least one output coupled to the phase adjustment stage. Optionally, the power amplifier for producing an amplified RF signal from an input RF signal wherein the digital signal processing circuitry comprises a lookup table comprising a plurality of gain compensation values and a plurality of phase compensation values.

In another embodiment, a method for producing an amplified radio frequency (RF) signal from an input RF signal comprises: receiving the input signal and producing a first split signal and a second split signal; producing a digital representation of the first split signal; producing a gain control signal and a phase control signal from the first split signal; producing a delayed representation of the second split signal; adjusting a gain and phase of the delayed representation of the second split signal based respectively on the gain control signal and the phase control signal to produce a phase-adjusted and gain-adjusted signal; and producing the amplified RF signal by amplifying the phase-adjusted and gain-adjusted signal.

Optionally, the producing a delayed representation of the input second split signal from the second split signal of the method for producing an amplified radio frequency (RF) signal from an input RF signal may comprise filtering the second split signal with a surface acoustic wave (SAW) filter. Optionally, the delayed representation of the second split signal of the method for producing an amplified radio frequency (RF) signal from an input RF signal may have a delay ranging from about 500 nanoseconds to about 2 microseconds. Optionally, the delayed representation of the second split signal of the method for producing an amplified radio frequency (RF) signal from an input RF signal may have a frequency in the range of about 8.5 MHz-500 MHz.

Optionally, the method for producing an amplified radio frequency (RF) signal from an input RF signal may further comprise calibrating a field programmable gate array to produce a delay that is compatible with a delay of the delayed representation of the second split signal produced by the radio frequency delay circuit. Optionally, the method for producing an amplified radio frequency (RF) signal from an input RF signal may further comprise detecting a radio frequency envelope of the first split signal.

Optionally, the method for producing an amplified radio frequency (RF) signal from an input RF signal may further comprise: converting the radio frequency envelope of the first split signal to a digital representation of the radio frequency envelope. Optionally, the method for producing an amplified radio frequency (RF) signal from an input RF signal may further comprise: converting the gain control signal to an analog representation of the gain control signal. Optionally, the method for producing an amplified radio frequency (RF) signal from an input RF signal may further comprise: converting the phase control signal to an analog representation of the phase control signal.

Optionally, producing a gain control signal and a phase control signal from the first split signal of the method for producing an amplified radio frequency (RF) signal from an input RF signal may comprise retrieving a plurality of gain compensation values and a plurality of phase compensation values from a lookup table.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a schematic illustration of an RF power amplifier.

FIG. 2 is a graph of power at the output of a RF power amplifier over time, showing an undesirable overshoot.

FIG. 3 is a schematic illustration of one embodiment of an exemplary RF power amplifier.

FIG. 4 is a schematic illustration of another embodiment of an exemplary RF power amplifier.

FIG. 5 illustrates a power amplifier of one of the types described herein coupled to an MRI coil.

FIG. 6 is a flowchart of a method of operation of a power amplifier according to an embodiment of the present technology.

### DETAILED DESCRIPTION

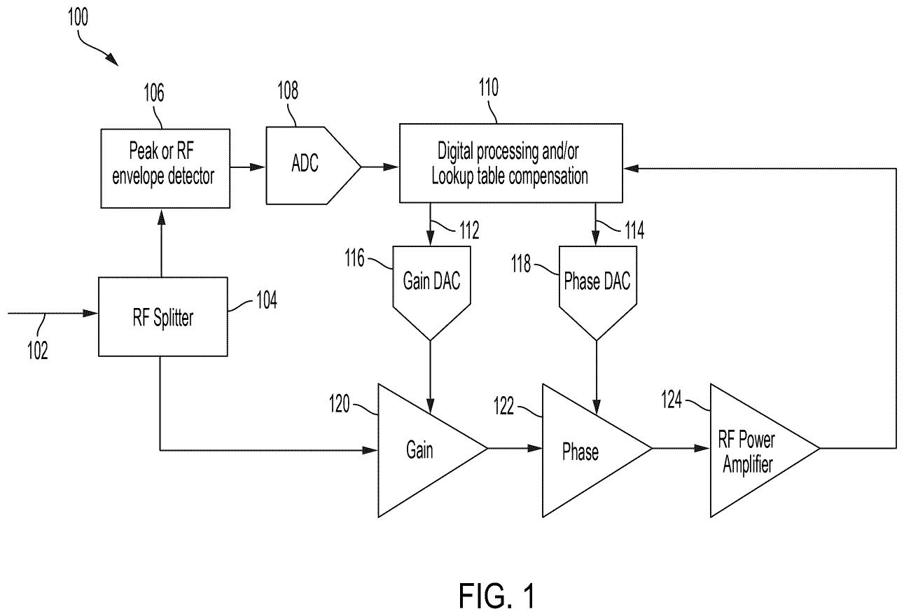

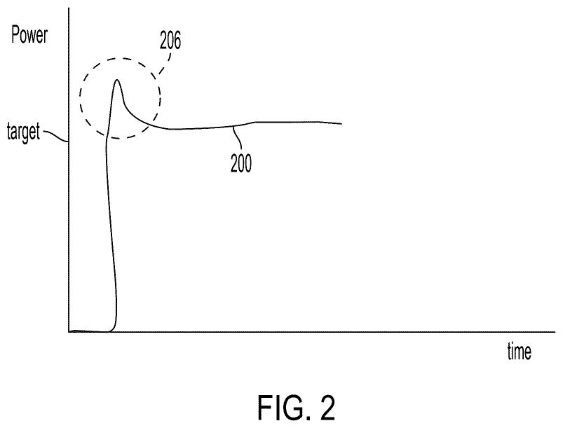

The inventors have appreciated that RF power amplifiers like the one illustrated in FIG. 1 produce pulses with undesirable overshoot. FIG. 2 shows a pulse 200 with an undesirable overshoot. FIG. 2 illustrates the output of the RF power amplifier stage 124 with time presented on the x axis and power presented on the y axis. As shown in FIG. 2, the pulse output of the RF power amplifier is not an ideal square-wave pulse but instead has an undesirable power overshoot 206.

Accordingly, there exists a need for a RF power amplifier that produces better square wave pulses than RF power amplifiers, without the undesirable overshoot.

Described herein is a feed-forward design of a RF power amplifier with circuitry to provide compatible delays for a digital control portion and an analog processing portion of the amplifier. The RF input signal to the system is an analog signal that is split and fed forward to digital processing circuity in a digital control portion. The digital processing circuitry uses the RF input signal to determine phase and gain adjustments to be applied to the RF signal in an analog domain. An RF delay stage delays the analog RF input signal in an analog processing portion by an amount sufficient to enable proper determination of the phase and gain adjustments in the digital domain and timely application of these adjustments to the analog RF signal. Another delay stage may also be provided in the digital control portion to delay the digital representation of the RF input signal to calibrate with the delay of the analog RF input signal caused by the RF delay stage in the analog processing portion.

Accordingly, some aspects of the described technology provide a RF power amplifier including a feed-forward design having a RF delay circuit, gain adjustment component, and phase adjustment component to provide a compensated RF signal. The RF power amplifier is described in some embodiments with particular application to Magnetic Resonance Imaging (MRI) systems, with the output of the feed-forward RF power amplifier being provided to an MRI system. However, RF power amplifiers and associated circuitry as described herein also may be applicable to other applications requiring a high-frequency pulsed power signal. One example of another such application is semiconductor manufacturing equipment such as semiconductor etching tools.

An overshoot occurs in the conventional RF power amplifier due to the inherent behavior of the RF power amplifier stage. The gain of the power amplifier is different at different power levels. When the input power is low, the gain of the RF power amplifier stage is also low so a Variable Gain Amplifier (VGA) stage must be set to a high gain. When there is a pulse with a sharp rise time, the digital control is unable to decrease the VGA stage gain sufficiently fast to maintain the desired system gain, which leads to the overshoot. Aspects of the present technology limit overshoot in the power pulse output by the RF power amplifier, particularly in comparison with the overshoot of conventional RF power amplifiers. Adding the delay circuity in the analog processing portion allows extra time to overcome this shortcoming.

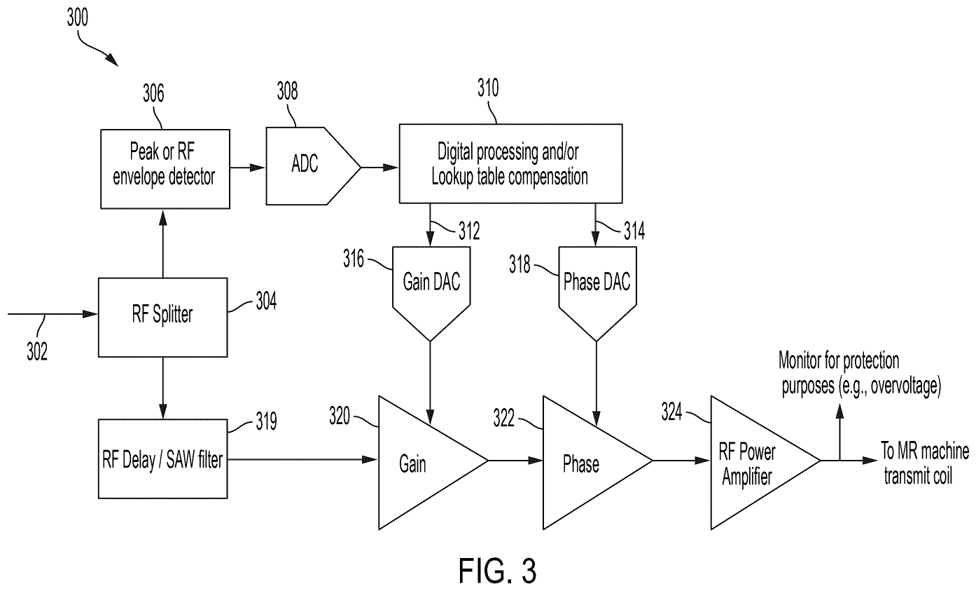

FIG. 3 is a schematic illustration of one embodiment of an exemplary RF power amplifier. As shown in FIG. 3, the exemplary RF power amplifier 300 includes a RF splitter 304 receiving an input RF signal 302. The RF splitter 304 produces a first split signal and a second split signal. The exemplary RF power amplifier 300 also includes a peak or radio frequency envelope detector 306 electrically connected to the RF splitter 304. The peak or radio frequency envelope detector 306 may be the same as peak or radio frequency envelope detector 106, described previously, and may operate in the same manner. The first split signal may be the signal provided from the RF splitter 304 to the peak or radio frequency envelope detector 306. The second split signal may be the signal provided from the RF splitter 304 to the RF delay/Saw filter 319. The peak or radio frequency envelope detector 306 produces a demodulated signal, which in this example is provided to the ADC 308.

The exemplary RF power amplifier 300 also includes the ADC 308, electrically connected to the peak or radio frequency envelope detector 306. The output of the ADC 308 is a digital representation of the first split signal. The exemplary RF power amplifier 300 also includes digital processing circuitry 310 electrically connected to the analog to digital converter 308. The digital processing circuitry 310 may include a lookup table for determining gain and phase adjustments to be applied to the radio frequency input signal 302 in the analog domain. The digital processing circuitry 310 outputs a gain control signal 312 and a phase control signal 314. The exemplary RF power amplifier 300 includes a first DAC converter 316 electrically connected to the digital processing circuitry 310 and configured to receive as input the gain control signal 312 and to produce an analog representation of the gain control signal 312. The exemplary RF power amplifier 300 includes a second DAC 318 electrically connected to the digital processing circuitry 310 and configured to receive as input the phase control signal 314 and to produce an analog representation of the phase control signal 314. The radio frequency envelope detector 306, the ADC 308, the digital processing circuitry 310, the gain control signal 312, the phase control signal 314 constitute a digital control portion of the RF power amplifier 300. In other embodiments, the digital control portion may include additional components or fewer components.

The exemplary RF power amplifier 300 includes a RF delay circuit 319 electrically connected to the RF splitter. The RF delay circuit 319 produces a delayed representation of the second split signal. The RF delay circuit 319 is configured to delay the RF input signal 302 by an amount sufficient to enable the digital control portion of the RF power amplifier 300 to determine the gain and phase adjustments to be applied to the RF input signal, and to apply these gain and phase adjustments to the RF input signal in a timely manner, meaning at the point of the RF input signal to which the gain and phase adjustments are intended to be applied. If the delay imposed by the RF delay circuit 319 is not sufficiently long, then the RF input signal will pass through the RF amplifier 300 before the gain and phase adjustments are determined and applied by the digital control portion due to the time required for the digital control portion to determine the gain and phase adjustments.

The RF delay circuit 319 may take various forms. In some embodiments, the RF delay circuit 319 is a Surface Acoustic Wave (SAW) filter. SAW filters are passive components whose mechanical characteristics such as material and dimensions impact the frequencies of signals that will pass through them. Typically, a SAW filter will exhibit a passband, passing frequencies within a given range. As a result, SAW filters are typically used for filtering signals in RF systems.

When the RF delay circuit 319 comprises a SAW filter the SAW filter is being used in an unconventional manner, for the purpose of delaying the signal passing through it as opposed to for the purpose of filtering the signal. That is, the SAW filter introduces a delay of the analog RF signal received from the RF splitter 304. The SAW filter used may be selected based on the amount of delay it will provide, to ensure that the amount is sufficient as explained above. Moreover, since the SAW filter will exhibit bandpass operation, the filter used should have a passband which passes the desired range of signal frequencies. Further still, since the SAW filter in the context of power amplifier 300 is not being used for its filtering function, the filter may be selected to provide low attenuation. Thus, in some embodiments, the SAW filter may be designed or chosen to exhibit a desired time delay, passband, and attenuation. As an example, the SAW filter may be selected to impart a delay ranging from about 500 nanoseconds to about 2 microseconds, exhibit a passband from approximately 100 kHz up to approximately 200 MHz, and exhibit low attenuation. Such performance characteristics may be particularly suitable for powering medical systems (e.g., MRI systems) and semiconductor manufacturing equipment.

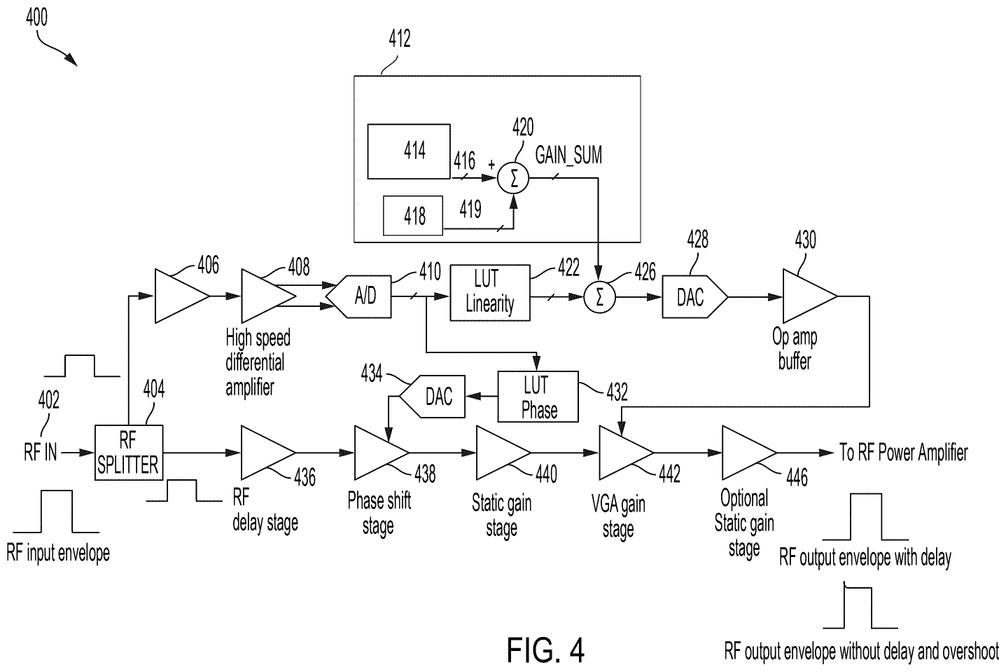

In some embodiments, a delay may be introduced into the digital control portion of the RF power amplifier. Preferably, the delay introduced into the digital control portion is compatible with the delay introduced by the RF delay circuit 319. Preferably, the delay introduced by the RF delay circuit 319 is not tunable or variable. Rather, the delay introduced by the RF delay circuit 319 is preferably set by selection of the SAW filter. Preferably, the delay introduced by the digital control portion is set to account for the delay of the RF delay circuit 319 in the analog signal path. In some embodiments as explained below with respect to FIG. 4, the digital control path includes a Field Programmable Gate Array (FPGA), which introduces a fixed delay in the digital control portion. Preferably, the delay introduced by the RF delay circuit 319 in the analog signal path (e.g., a SAW filter) is longer than the fixed delay in the digital control portion. Preferably, the delay introduced by the RF delay circuit 319 (e.g., a SAW filter) is longer than the time required by the digital control portion to process the signal from the RF splitter 304 and generate the gain and phase adjustments. For example, if a SAW filter introduces a delay of one microsecond and the RF signal is processed by the digital control portion in 800 nanoseconds, then a delay of 200 nanoseconds may be introduced in the digital control portion such that the time to generate the gain and phase adjustments from the signal output from the RF splitter 304 matches the delay introduced by the SAW filter. In this manner, the gain and phase adjustments provided by the Gain DAC 316 and Phase DAC 318 will be applied at an appropriate time to the delayed analog RF signal from the RF delay circuit 319.

In some embodiments, a gain adjustment stage 320 is electrically connected to an output of the RF delay circuit 319 and the first DAC 116 and is configured to receive the analog representation of the gain control signal 112 and the analog signal from the RF delay circuit 319. The exemplary RF power amplifier 300 includes a phase adjustment stage 322 electrically connected to the gain adjustment stage 320 and the second DAC 318 and is configured to receive the analog representation of the phase control signal 314. In another variant of the exemplary RF power amplifier 300, the gain adjustment stage 320 and the phase adjustment stage 322 may also be connected in a different order. In this variant, the phase adjustment stage 322 is electrically connected to the RF delay circuit 319 and the second DAC 318 and is configured to receive the analog representation of the phase control signal and the analog signal from the RF delay circuit 319. In this variant, the gain adjustment stage 320 is electrically connected to the phase adjustment stage 322 and the first digital to analog converter 316 and is configured to receive the analog representation of the gain control signal 312 and the analog signal from the phase adjustment stage 322. Thus, each of the gain adjustment stage 320 and the phase adjustment stage 322 may be directly or indirectly coupled to the RF delay stage 319. The phase adjustment stage 322 and the gain adjustment stage 320 collectively produce a phased adjusted and gain adjusted signal.

The exemplary RF power amplifier 300 also includes a RF power amplifier stage 324 electrically connected to an output of the phase adjustment stage 322. In the variant described above, the RF power amplifier stage 324 is electrically connected to an output of the gain adjustment stage 320. The RF power amplifier stage 324 produces an amplified RF signal. The digital processing circuity 310 is further configured to receive an output of the ADC 308 and to use it to adjust the gain control signal 312 and the phase control signal 314. The output of the RF power amplifier stage 324 may also be electrically connected to a system to be powered, such as an MRI system (e.g., a transmission coil of an MRI machine), a semiconductor processing tool, or other RF-based system. The RF delay circuit 319, the first DAC 116, the phase adjustment stage 322, the gain adjustment stage 320, the RF power amplifier stage 324 constitute an analog processing portion of the exemplary RF power amplifier 300. In other embodiments, the analog processing portion may include additional components or fewer components.

FIG. 4 is a schematic illustration of another exemplary embodiment of an exemplary RF power amplifier. As shown in FIG. 4, the exemplary RF power amplifier 400 includes a RF splitter 404 receiving an input RF signal 402. The exemplary RF power amplifier 400 also includes a log detector 406 having an input electrically connected to an output of the RF splitter 404. In some embodiments, the log detector 406 is an AD8310 from Analog Devices of Wilmington, Massachusetts, having a 40 nanosecond delay to one percent, although other log detectors may be used in alternative embodiments.

The exemplary RF power amplifier 400 also includes a differential amplifier 408 having an input electrically connected to an output of the log detector 406. In at least some embodiments, the differential amplifier 408 is a high-speed differential amplifier. The exemplary RF power amplifier 400 may also include an analog to digital converter 410, having two inputs electrically connected to two corresponding outputs of the differential amplifier 408. In some embodiments, the analog to digital converter 410 is a LTC228 available from Analog Devices. Preferably, the analog to digital converter 410 has a sampling rate of approximately 60 million samples per second (MSPS), corresponding to a sampling period of approximately 16.7 nanoseconds. Preferably, the analog to digital converter 410 includes a pipeline core having five stages.

The exemplary RF power amplifier 400 may also include a Field Programmable Gate Array (FPGA) 412 electrically connected to an output of the analog to digital converter 410. The FPGA 412 of the exemplary RF power amplifier 400 may include a calculated FPGA CONTROLLED GAIN ADJUSTMENT stage 414 that produces a FPGA CONTROLLED GAIN ADJUSTMENT signal 416 that varies depending on operational conditions. The FPGA 412 of the exemplary RF power amplifier 400 may include a NOMINAL_GAIN register 418 to allow for a programmable static gain setting through the provision of NOMINAL_GAIN signal 419. The FPGA 412 of the exemplary RF power amplifier 400 may have a summation 420 having an input electrically connected to receive the FPGA CONTROLLED GAIN ADJUSTMENT signal 416 and another input to receive the NOMINAL_GAIN signal 419.

Some additional components of the RF power amplifier 400 may be part of the FPGA 412 even though not contained with the box labeled 412. For example, the FPGA 412 of the exemplary RF power amplifier 400 may also include a linearity look up table 422 having an input electrically connected to an output of the analog to digital converter 410. The linearity look up table 422 is used to calibrate the amplifier to provide a constant gain across different power levels. The FPGA 412 samples the RF envelope of the RF input 402 which is provided to the linearity look up table 422 to determine the correct gain setting to use, which is provided to the DAC 428 via the summation 426. Thus, as shown, the FPGA 412 of the exemplary RF power amplifier 400 may also include a summation 426 having an input electrically connected to an output of the summation 420 to receive a signal GAIN_SUM and another input electrically connected to an output of the look up table 422. Collectively, the lookup table 422, the summation 420, and the summation 426 operate to determine a gain control signal.

The FPGA 412 of the exemplary RF power amplifier 400 may also include a lookup table 432 having an input electrically connected to the output of the analog to digital converter 410. The lookup table 432 is used to determine a phase control signal, and may in at least some embodiments operate to maintain a constant phase offset from the input signal to output signal over different power levels. The exemplary RF power amplifier 400 may include a first digital to analog converter 428 having an input electrically connected to an output of the summation 426. The exemplary RF power amplifier 400 may include an operational amplifier buffer 430 (“Op amp buffer”) having an input electrically connected to an output of the first digital to analog converter 428. The output of the operational amplifier buffer 430 is an analog representation of the gain control signal. The exemplary RF power amplifier 400 may also include a second digital to analog converter 434 having an input electrically connected to an output of the lookup table 432. The output of the second digital to analog converter 434 is an analog representation of the phase control signal.

The exemplary RF power amplifier 400 of FIG. 4 is a more detailed representation of the exemplary RF power amplifier 300 of FIG. 3. In particular, the digital control portion of the exemplary RF power amplifier 400 of FIG. 4 includes the Field Programmable Gate Array (FPGA) 412, the analog to digital converter 410, FPGA CONTROLLED GAIN ADJUSTMENT stage 414, the NOMINAL_GAIN register 418, the summation 420, the look up table 422, the summation 426, and the lookup table 432.

The exemplary RF power amplifier 400 may include a RF delay stage 436 having an input electrically connected to an output of the RF splitter 404. In some embodiments, the RF delay circuit is a Surface Acoustic Wave (SAW) filter. Here the SAW filter is used to introduce a delay of the analog RF signal received from the RF splitter 404.

In some embodiments, a phase adjustment stage 438 is electrically connected to an output of the RF delay stage 436 and the second digital to analog converter 434, and is configured to receive the analog representation of the phase control signal and the analog signal from the RF delay stage 436. The exemplary RF power amplifier 400 may include a first static gain stage 440 having an input electrically connected to an output of the phase adjustment stage 438. The static gain stage 440 compensates for the attenuation introduced by the RF delay circuit 319 (e.g., the SAW filter). The exemplary RF power amplifier 400 may include a gain adjustment stage 442 having an input electrically connected to an output of the first static gain stage 440 and another input electrically connected to the operational amplifier buffer 430. Optionally, the gain adjustment stage 442 may be a variable gain amplifier. A variable-gain amplifier (VGA) is an electronic amplifier that varies its gain depending on a control voltage. VGAs may be used for amplitude modulation. A voltage-controlled amplifier can be constructed by first creating a voltage-controlled resistor, which is used to set the amplifier gain. The voltage-controlled resistor can be produced with a junction field-effect transistor (JFET).

The exemplary RF power amplifier 400 may include a second static gain stage 446 having an input electrically connected to an output of the gain adjustment stage 442. The output of the second static gain stage 446 may be provided to a high powered RF amplifier. In some embodiments, the output of the second static gain stage 446 is electrically connected to an input of a transmission coil of a Magnetic Resonance Imaging (MRI) system or to the input of semiconductor manufacturing equipment.

In another variant of the exemplary RF power amplifier 400, the gain adjustment stage 442 and the phase adjustment stage 438 may also be connected in a different order. In this variant, the gain adjustment stage 442 is electrically connected to the RF delay stage 436 and the output of the operational amplifier buffer 430, and is configured to receive the analog representation of the gain control signal and the analog signal from the RF delay stage 436. In this variant, the input of the first static gain stage 440 is electrically connected to the output of the gain adjustment stage 442. In this variant, the inputs of the phase adjustment stage 438 are electrically connected to the output of the first static gain stage 440 and the digital to analog converter 434, and the phase adjustment stage 438 is configured to receive the analog representation of the phase control signal and the analog signal from the first static gain stage 440. In this variant, the input of the second static gain stage 446 is electrically connected to the output of the phase adjustment stage 438. The output of the second static gain stage 446 may be electrically connected to an input of a transmission coil of a Magnetic Resonance Imaging (MRI) system or to the input of semiconductor manufacturing equipment.

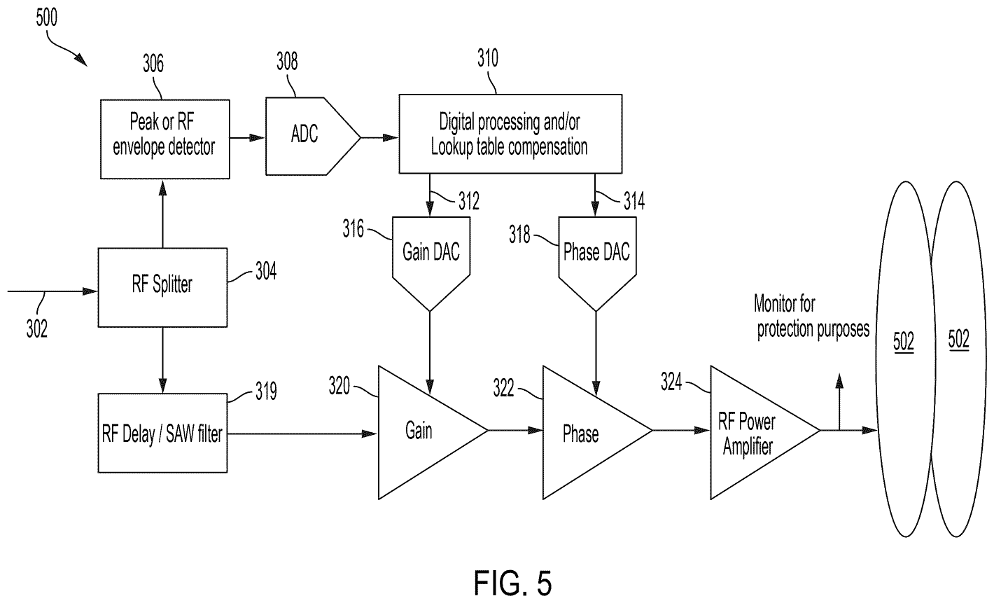

FIG. 5 illustrates a power amplifier of the types described herein coupled to a magnetic resonance imaging (MRI) coil 502. In one embodiment, the MRI coil 502 is a pair of coils. The MRI coil 502 may include an RF transmit coil, and an RF receive coil. A main magnet (not shown) in the MRI device polarizes protons in tissue in a human or animal subject in an examination region. The RF transmit coil localizes and spatially encodes the positions of the protons. The RF amplifier produces an RF signal which causes the RF transmit coil to transmit RF pulses that excite protons in the human or animal subject. The RF receive coil receives a Magnetic Resonance (MR) signal produced in response to the protons returning to the pre-excite state. The received MR signal is processed to generate an image. In some embodiments, there is a one-channel connection between the RF amplifier and the MRI coil 502. In another embodiment, there is a multi-channel (e.g., two-channel) connection between the RF amplifier and the MRI coil 502.

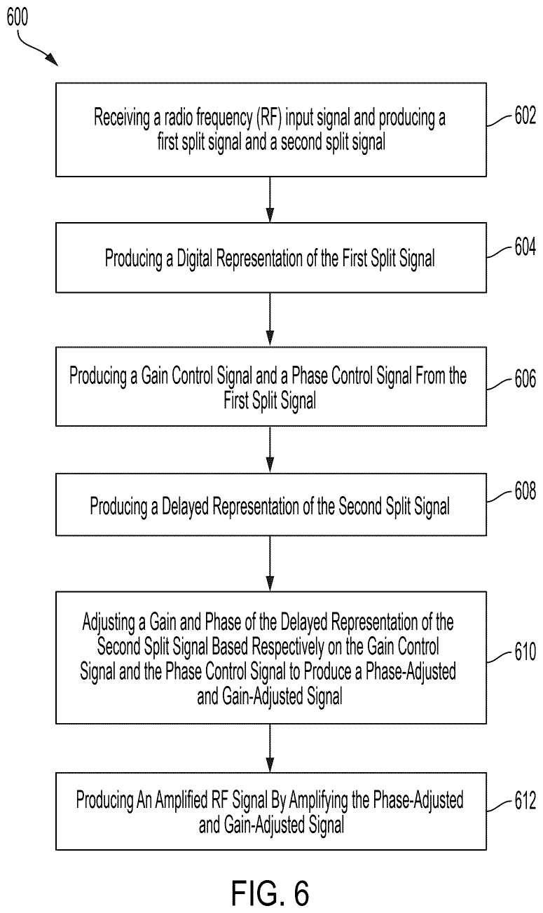

FIG. 6 is a flowchart of a method of operation of a power amplifier according to an embodiment of the present technology. In step 602, a radio frequency (RF) input signal is received, and a first split signal and a second split signal are produced. The first split signal and the second split signal may be produced by an RF splitter (e.g., the RF splitter 304 shown in FIG. 3). In step 604, a digital representation of the first split signal is produced. The digital representation of the first split signal may be produced by and analog to digital converter (e.g., the analog to digital converter 308 shown in FIG. 3). In step 606, a gain control signal and a phase control signal are produced from the first split signal. The gain control signal may be produced from the first split signal by a digital processing circuit (e.g., the digital processing and/or lookup table compensation 310 and the gain digital to analog converter 316 of FIG. 3). The phase control signal may be produced from the first split signal by the digital processing circuit (e.g., the digital processing and/or lookup table compensation 310 and the phase digital to analog converter 318 of FIG. 3). In step 608, a delayed representation of the second split signal is produced. The delayed representation of the second split signal may be produced by an analog delay component (e.g., the RF delay/SAW filter 319 shown in FIG. 3). In step 610, a gain and phase of the delayed representation of the second split signal is adjusted based respectively on the gain control signal and the phase control signal to produce a phase-adjusted and gain-adjusted signal. The gain and phase of the delayed representation of the second split signal may be gain adjusted by a gain adjustment circuit (e.g., the gain adjustment 320 shown in FIG. 3) and may be phase adjusted by a phase adjustment circuit (e.g., the phase adjustment 322 shown in FIG. 3). In step 612, an amplified RF signal is produced by amplifying the phase-adjusted and gain-adjusted signal. The amplified RF signal may be produced by a power amplifier stage (e.g., the RF power amplifier stage 324 shown in FIG. 3).

It should be apparent to one of ordinary skill in the art that the embodiments disclosed herein are not limited to a particular computer system platform, processor, operating system, network, or communication protocol. Also, it should be apparent that the embodiments disclosed herein are not limited to a specific architecture or programming language.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element unless the context indicates otherwise. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Use of at least one of and a list of elements (e.g., A, B, C) is intended to cover any one selection from A, B, C (e.g., A), any two selections from A, B, C (e.g., A and B), any three selections (e.g., A, B, C), etc., and any multiples of each selection. Having thus described several aspects of at least one embodiment of this technology, it is to be appreciated various alterations, modifications, and improvements will readily occur to those skilled in the art. Such alterations, modifications, and improvements are intended to be part of this disclosure, and are intended to be within the spirit and scope of this disclosure. Accordingly, the foregoing description and drawings are by way of example only.

What is claimed is:

1. A power amplifier for producing an amplified radio frequency (RF) signal from an input RF signal, the power amplifier comprising:
an RF splitter configured to receive the input RF signal and split the input RF signal into a first split signal and a second split signal;
a digital control portion comprising:
digital processing circuitry coupled to the RF splitter, configured to receive a digital representation of the first split signal and to produce a gain control signal and a phase control signal;
an analog processing portion comprising:
an RF delay stage coupled to the RF splitter, configured to receive the second split signal and to produce a delayed representation of the second split signal;
a gain adjustment stage coupled directly or indirectly to the radio frequency delay stage, configured to receive the gain control signal and to adjust a gain based on the gain control signal;
a phase adjustment stage coupled directly or indirectly to the radio frequency delay stage, configured to receive the phase control signal and to adjust a phase based on the phase control signal, wherein the gain adjustment stage and the phase adjustment stage collectively produce a phase-adjusted and gain-adjusted signal; and
an RF power amplifier stage, configured to receive the phase-adjusted and gain-adjusted signal and to produce the amplified RF signal.

2. The power amplifier for producing an amplified RF signal from an input RF signal of claim 1, wherein the RF delay stage comprises a surface acoustic wave (SAW) filter.

3. The power amplifier for producing an amplified RF signal from an input RF signal of claim 1, wherein the RF delay stage is configured to produce the delayed representation of the second split signal having a delay ranging from about 500 nanoseconds to about 2 microseconds.

4. The power amplifier for producing an amplified RF signal from an input RF signal of claim 1, wherein the delayed representation of the input signal has a frequency ranging from about 8.5 MHz to about 500 MHz.

5. The power amplifier for producing an amplified RF signal from an input RF signal of claim 1, wherein the digital processing circuitry of the digital control portion further comprises a field programmable gate array calibrated to produce a delay that is compatible with a delay of the delayed representation of the second split signal produced by the RF delay stage.

6. The power amplifier for producing an amplified RF signal from an input RF signal of claim 1, wherein the digital control portion further comprises:
a radio frequency envelope detector coupled to the RF splitter, configured to receive the first split signal, and configured to output a demodulated signal.

7. The power amplifier for producing an amplified RF signal from an input RF signal of claim 6, wherein the digital control portion further comprises:
an analog to digital converter having at least one input coupled to the radio frequency envelope detector and at least one output coupled to the digital signal processing circuitry.

8. The power amplifier for producing an amplified RF signal from an input RF signal of claim 7, further comprising:
a gain digital to analog converter having at least one input coupled to the digital signal processing circuitry and having at least one output coupled to the gain adjustment stage.

9. The power amplifier for producing an amplified RF signal from an input RF signal of claim 7, further comprising:
a phase digital to analog converter having at least one input coupled to the digital signal processor and having at least one output coupled to the phase adjustment stage.

10. The power amplifier for producing an amplified RF signal from an input RF signal of claim 1 wherein the digital signal processing circuitry comprises a lookup table comprising a plurality of gain compensation values and a plurality of phase compensation values.

11. A method for producing an amplified radio frequency (RF) signal from an input RF signal comprising:
receiving the input signal and producing a first split signal and a second split signal;
producing a digital representation of the first split signal;
producing a gain control signal and a phase control signal from the first split signal;
producing a delayed representation of the second split signal;
adjusting a gain and phase of the delayed representation of the second split signal based respectively on the gain control signal and the phase control signal to produce a phase-adjusted and gain-adjusted signal;
and
producing the amplified RF signal by amplifying the phase-adjusted and gain-adjusted signal.

12. The method for producing an amplified radio frequency (RF) signal from an input RF signal of claim 11 wherein the producing a delayed representation of the input second split signal from the second split signal comprises filtering the second split signal with a surface acoustic wave (SAW) filter.

13. The method for producing an amplified radio frequency (RF) signal from an input RF signal of claim 11 wherein the delayed representation of the second split signal has a delay ranging from about 500 nanoseconds to about 2 microseconds.

14. The method for producing an amplified radio frequency (RF) signal from an input RF signal of claim 11 wherein the delayed representation of the second split signal has a frequency ranging from about 8.5 MHz to about 500 MHz.

15. The method for producing an amplified radio frequency (RF) signal from an input RF signal of claim 1 further comprises calibrating a field programmable gate array to produce a delay that is compatible with a delay of the delayed representation of the second split signal produced by the radio frequency delay circuit.

16. The method for producing an amplified radio frequency (RF) signal from an input RF signal of claim 11 further comprising detecting a radio frequency envelope of the first split signal.

17. The method for producing an amplified radio frequency (RF) signal from an input RF signal of claim 16 further comprising:
converting the radio frequency envelope of the first split signal to a digital representation of the radio frequency envelope.

18. The method for producing an amplified radio frequency (RF) signal from an input RF signal of claim 17 further comprising:
converting the gain control signal to an analog representation of the gain control signal.

19. The method for producing an amplified radio frequency (RF) signal from an input RF signal of claim 17 further comprising:
converting the phase control signal to an analog representation of the phase control signal.

20. The method for producing an amplified radio frequency (RF) signal from an input RF signal of claim 11 wherein producing a gain control signal and a phase control signal from the first split signal comprises retrieving a plurality of gain compensation values and a plurality of phase compensation values from a lookup table.
